(19) United States
(12) Patent Application Publication
(10) Pub. No.: US 2025/0280662 A1
(43) Pub. Date: Sep. 4, 2025

(54) DISPLAY PANEL AND DISPLAY DEVICE

(71) Applicants: Yungu (Gu’an) Technology Co., Ltd., Langfang (CN); Hefei Visionox Technology Co., Ltd., Hefei (CN)

(72) Inventors: Junhui LOU, Langfang (CN); Lihua WANG, Hefei (CN)

(73) Assignees: Yungu (Gu’an) Technology Co., Ltd., Langfang (CN); Hefei Visionox Technology Co., Ltd., Hefei (CN)

(21) Appl. No.: 19/010,210

(22) Filed: Jan. 6, 2025

(30) Foreign Application Priority Data
Feb. 29, 2024 (CN) 202410232781.0

(51) Int. Cl. H10K 59/122; H10K 59/40

(52) U.S. Cl. CPC H10K 59/122; H10K 59/40

(57) ABSTRACT

Embodiments of the present disclosure provide a display panel and a display device. The display panel includes: a substrate; a pixel defining layer; an isolation structure disposed on the substrate, an orthographic projection of the isolation structure on the substrate being located outside an orthographic projection of the pixel opening on the substrate, and the isolation structure including a first isolation structure and a second isolation structure which are spaced apart and insulated from each other; and a functional layer including a first electrode, a touch electrode and a second electrode The touch electrode is configured to implement a touch function of the display panel, and the functional layer includes both the touch electrode and the first electrode. The functional layer also includes the second electrode, and by rationally positioning the touch electrode and the second electrode.

### CROSS REFERENCE TO RELATED APPLICATION

The present application claims priority to Chinese Patent Application No. 202410232781.0 filed on Feb. 29, 2024, and titled “DISPLAY PANEL AND DISPLAY DEVICE”, which is incorporated herein by reference in its entirety.

### TECHNICAL FIELD

The present disclosure relates to the technical field of display equipment, and particularly to a display panel and a display device.

### BACKGROUND ART

An organic light-emitting diode (OLED) is an active light-emitting device. Compared with a conventional liquid crystal display (LCD) method, OLED display technology does not require a backlight and has self-luminous properties. OLED display panels can significantly save energy and be made lighter and thinner, tolerate a wider range of temperature changes than LCD display panels, and have a larger viewing angle.

### SUMMARY OF THE INVENTION

Embodiments of the present disclosure provide a display panel and a display device, with a view to simplifying the structure of the display panel.

An embodiment in a first aspect of the present disclosure provides a display panel. The display panel includes: a substrate; a pixel defining layer disposed on the substrate and including a pixel defining portion and a pixel opening within which a light-emitting unit is disposed; an isolation structure disposed on the substrate, an orthographic projection of the isolation structure on the substrate being located outside an orthographic projection of the pixel opening on the substrate, and the isolation structure including a first isolation structure and a second isolation structure which are spaced apart and insulated from each other; and a functional layer including a first electrode, a touch electrode and a second electrode which are insulated and spaced apart from each other, the first electrode being located on a side of the light-emitting unit away from the substrate, the touch electrode being located on a side of the first isolation structure away from the substrate, and the second electrode being located on a side of the second isolation structure away from the substrate.

According to an implementation of the first aspect of the present disclosure, the display panel includes a plurality of touch areas, each of the touch areas is provided with the touch electrode, a non-touch area is formed between two adjacent ones of the touch areas, and the non-touch area is provided with the second electrode.

According to any one of the foregoing implementations of the first aspect of the present disclosure, the plurality of touch areas are distributed in an array in a first direction and a second direction.

According to any one of the foregoing implementations of the first aspect of the present disclosure, the touch electrode includes:
a first touch portion arranged to extend in the first direction, a plurality of first touch portions being distributed at intervals in the second direction; and
a second touch portion connecting two adjacent ones of the first touch portions;
where a plurality of pixel openings are distributed in an array in the first direction and the second direction, two or more rows of pixel openings are arranged between two adjacent ones of the first touch portions, and the second electrode is correspondingly arranged between the two adjacent ones of the first touch portions and between two adjacent rows of pixel openings.

According to any one of the foregoing implementations of the first aspect of the present disclosure, the width of the second electrode in the second direction is the same as the width of the first touch portion in the second direction.

According to any one of the foregoing implementations of the first aspect of the present disclosure, the first electrode includes a first sub-electrode portion and a second sub-electrode portion, the first sub-electrode portion being located between two adjacent ones of the first touch portions, a plurality of first sub-electrode portions being arranged at intervals in the second direction, and the second sub-electrode portion connecting two adjacent ones of the first sub-electrode portions.

According to any one of the foregoing implementations of the first aspect of the present disclosure, at least a part of the second sub-electrode portion and the second touch portion are respectively arranged on two sides of the same first touch portion in the first direction.

According to any one of the foregoing implementations of the first aspect of the present disclosure, the second electrode is arranged between two adjacent ones of the first touch portions and between two adjacent ones of the first sub-electrode portions.

According to any one of the foregoing implementations of the first aspect of the present disclosure, the second electrode includes a first virtual electrode arranged to extend in the first direction.

According to any one of the foregoing implementations of the first aspect of the present disclosure, the first virtual electrode is located between two adjacent ones of the first touch portions in the first direction.

According to any one of the foregoing implementations of the first aspect of the present disclosure, the first virtual electrode extends by the same width as the first touch portion in the second direction.

According to any one of the foregoing implementations of the first aspect of the present disclosure, a plurality of first virtual electrodes are arranged side by side in the second direction, and the second electrode further includes a second virtual electrode connecting two adjacent ones of the first virtual electrodes in the second direction.

According to any one of the foregoing implementations of the first aspect of the present disclosure, the shape of an extension path of the second virtual electrode is the same as the shape of an extension path of the second touch portion.

According to any one of the foregoing implementations of the first aspect of the present disclosure, the second virtual electrode extends by the same width in the first direction as the second touch portion in the first direction.

According to any one of the foregoing implementations of the first aspect of the present disclosure, two adjacent ones of the touch areas are spaced apart by the same distance in the first direction and/or the second direction; and
the width of the second electrode between two adjacent ones of the touch areas in the first direction is the same, and/or the length of the second electrode between two adjacent ones of the touch areas in the second direction is the same.

According to any one of the foregoing implementations of the first aspect of the present disclosure, the number of touch electrodes provided in each of the touch areas is the same.

According to any one of the foregoing implementations of the first aspect of the present disclosure, a plurality of pixel openings are distributed in an array in a first direction and a second direction, the first direction being a row direction, and the second electrode being correspondingly located between two adjacent rows of pixel openings.

According to any one of the foregoing implementations of the first aspect of the present disclosure, a plurality of second electrodes are arranged side by side at intervals in the first direction.

According to any one of the foregoing implementations of the first aspect of the present disclosure, the second electrode and one or more of the pixel openings are arranged side by side in the second direction, or the plurality of second electrodes and the same pixel opening are arranged side by side in the second direction.

According to any one of the foregoing implementations of the first aspect of the present disclosure, the isolation structure is disposed on a side of the pixel defining portion away from the substrate;
or the pixel defining portion also encloses a clearance opening, and the isolation structure is located in the clearance opening and is spaced apart from an inner wall surface of the pixel defining portion facing the clearance opening.

According to any one of the foregoing implementations of the first aspect of the present disclosure, the first isolation structure includes a conductive portion and an insulating portion on a side of the conductive portion away from the substrate, the touch electrode being located on a side of the insulating portion away from the substrate,
and/or, the second isolation structure includes a conductive portion and an insulating portion on a side of the conductive portion away from the substrate, the second electrode being located on a side of the insulating portion away from the substrate,
where the first electrode and the conductive portion are electrically connected to each other.

According to any one of the foregoing implementations of the first aspect of the present disclosure, the insulating portion includes an inorganic insulation layer and/or an organic insulation layer.

According to any one of the foregoing implementations of the first aspect of the present disclosure, an orthographic projection of the conductive portion on the substrate is located within an orthographic projection of the insulating portion on the substrate.

According to any one of the foregoing implementations of the first aspect of the present disclosure, the conductive portion includes a first sub-layer and a second sub-layer on a side of the first sub-layer away from the substrate, the first sub-layer and the first electrode being electrically connected to each other, an orthographic projection of the first sub-layer on the substrate being located within an orthographic projection of the second sub-layer on the substrate, and the orthographic projection of the second sub-layer on the substrate being located within an orthographic projection of the insulating portion on the substrate.

According to any one of the foregoing implementations of the first aspect of the present disclosure, the conductive portion further includes a third sub-layer on a side of the first sub-layer facing the substrate, the orthographic projection of the first sub-layer on the substrate being located within an orthographic projection of the third sub-layer on the substrate.

According to any one of the foregoing implementations of the first aspect of the present disclosure, the second sub-layer and the third sub-layer are made of the same material.

An embodiment of a first aspect of the present disclosure further provides a display panel, including: a substrate; a pixel defining layer disposed on the substrate and including a pixel defining portion and a pixel opening; a light-emitting layer including a light-emitting unit located in the pixel opening; and a functional layer disposed on a side of the light-emitting layer and the pixel defining layer away from the substrate, the functional layer including a first electrode, a touch electrode and a second electrode which are insulated and spaced apart from each other, the first electrode being located on a side of the light-emitting unit away from the substrate.

According to an implementation of the first aspect of the present disclosure, the display panel further includes an isolation structure disposed on one side of the substrate, an orthographic projection of the isolation structure on the substrate being located outside an orthographic projection of the pixel opening on the substrate, the isolation structure including a first isolation structure and a second isolation structure which are spaced apart and insulated from each other, the touch electrode being located on a side of the first isolation structure away from the substrate, and the second electrode being located on a side of the second isolation structure away from the substrate.

According to any one of the foregoing implementations of the first aspect of the present disclosure, the first electrode is electrically connected to the isolation structure.

An embodiment of a first aspect of the present disclosure further provides a display panel, including: a substrate; an isolation structure disposed on the substrate, the isolation structure enclosing an isolation opening, and the isolation structure including a first isolation structure and a second isolation structure which are spaced apart and insulated from each other; a light-emitting layer including a light-emitting unit located at the isolation opening; and a functional layer including a first electrode, a touch electrode and a second electrode which are insulated and spaced apart from each other, the first electrode being located on a side of the light-emitting unit away from the substrate, the touch electrode being located on a side of the first isolation structure away from the substrate, and the second electrode being located on a side of the second isolation structure away from the substrate.

According to any one of the foregoing implementations of the first aspect of the present disclosure, the first isolation structure and the second isolation structure each include a conductive portion and an insulating portion on a side of the conductive portion away from the substrate, the touch electrode and the second electrode being located on a side of the insulating portion away from the substrate, and the first electrode and the conductive portion being connected to each other.

According to any one of the foregoing implementations of the first aspect of the present disclosure, the first isolation structure and the second isolation structure are spaced apart to create a gap, an orthographic projection of the light-emitting unit on the substrate is outside the gap, and at least a part of the first electrode is located in the gap to connect the conductive portions of the first isolation structure and the second isolation structure.

An embodiment in a second aspect of the present disclosure further provides a display device, including a display panel according to any one of the above-described embodiments in the first aspect.

In the display panel provided in the embodiment of the present disclosure, the display panel includes the substrate, the pixel defining layer, the isolation structure, and the functional layer, the pixel defining layer including the pixel defining portion and the pixel opening within which the light-emitting unit is disposed to achieve luminous display of the display panel. The orthographic projection of the isolation structure on the substrate is located outside the orthographic projection of the pixel opening on the substrate to improve the effect of the isolation structure on a luminous effect of the light-emitting unit. The functional layer includes the first electrode, the touch electrode and the second electrode, the first electrode being located on the side of the light-emitting unit away from the substrate to drive the light-emitting unit, and the isolation structure including the first isolation structure and the second isolation structure which are insulated from each other, to improve a short-circuit connection between the touch electrode on the first isolation structure and the second electrode on the second isolation structure. The touch electrode is configured to implement a touch function of the display panel, and the functional layer includes both the touch electrode and the first electrode, simplifying the structure of the display panel without separately providing a touch structure layer. The functional layer also includes the second electrode, and by rationally positioning the touch electrode and the second electrode, it is possible to improve the display effect of the display panel that is affected by the addition of the touch electrode in the functional layer.

### BRIEF DESCRIPTION OF THE DRAWINGS

By reading the following detailed description made with reference to the drawings for non-limiting embodiments, the other features, objectives and advantages of the present disclosure will become more apparent, in which the same or similar features are denoted by the same or similar reference numerals.

FIG. 1 is a top view of a display panel according to an embodiment of the present disclosure;

FIG. 2 is a partial top view of a display panel according to another embodiment of the present disclosure;

FIG. 3 is a sectional view along line A-A in FIG. 2;

FIG. 4 is a partial sectional view of a display panel according to another embodiment;

FIG. 5 is a partial top view of a display panel according to a further embodiment of the present disclosure;

FIG. 6 is a partial top view of a display panel according to a still further embodiment of the present disclosure;

FIG. 7 is a partial top view of a display panel according to yet another embodiment of the present disclosure;

FIG. 8 is a partial top view of a display panel according to yet another embodiment of the present disclosure;

FIG. 9 is a partial top view of a display panel according to yet another embodiment of the present disclosure;

FIG. 10 is a partial top view of a display panel according to an example;

FIG. 11 is a partial top view of a display panel according to another example; and

FIG. 12 is a partial sectional view of a display panel according to a further embodiment.

### LIST OF REFERENCE SIGNS

100. Substrate;
200. Pixel defining layer; 210. Pixel defining portion; 220. Pixel opening; 230. Light-emitting unit; 240. Clearance opening;
300. Isolation structure; 301. First isolation structure; 302. Second isolation structure; 310. Conductive portion; 311. First sub-layer; 312. Second sub-layer; 313. Third sub-layer; 320. Insulating portion;
400. Functional layer; 410. First electrode; 411. First sub-electrode portion; 412. Second sub-electrode portion; 420. Touch electrode; 421. First touch portion; 422. Second touch portion; 430. Second electrode; 431. First virtual electrode; 432. Second virtual electrode; 440. Signal line;
500. Pixel electrode layer; 510. Pixel electrode;
TA. Touch area; NTA. Non-touch area; AA. Display area; X. First direction; Y. Second direction.

### DETAILED DESCRIPTION OF EMBODIMENTS

The features and exemplary embodiments of the present disclosure in various aspects will be described in detail below. In the following detailed description, many specific details are set forth to comprehensively understand the present disclosure. However, it will be very apparent to those skilled in the art that the present disclosure may be implemented without some of these specific details. The following description of the embodiments is merely to provide a better understanding for the present disclosure by illustrating examples of the present disclosure. In the drawings and the following description, at least some of known structures and techniques are not shown to avoid unnecessary ambiguousness of the present disclosure; and for the case of clarity, the dimensions of part of the structure may be enlarged. In addition, the features, structures or characteristics described below may be combined, in any suitable manner, in one or more embodiments.

In the description of the present disclosure, it should be noted that “a plurality of” means two or more, unless otherwise specified. The orientation or position relationship indicated by the terms “upper”, “lower”, “left”, “right”, “inner”, “outer”, etc. is merely for the convenience of describing the present disclosure and simplifying the description, rather than indicating or implying that a device or element referred to must have a particular orientation or be constructed and operated in a particular orientation, and therefore should not be construed as limiting the present disclosure. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the present disclosure. In the description of the present disclosure, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection. For those of ordinary skill in the art, the specific meanings of the terms mentioned above in the present disclosure may be construed according to specific circumstances.

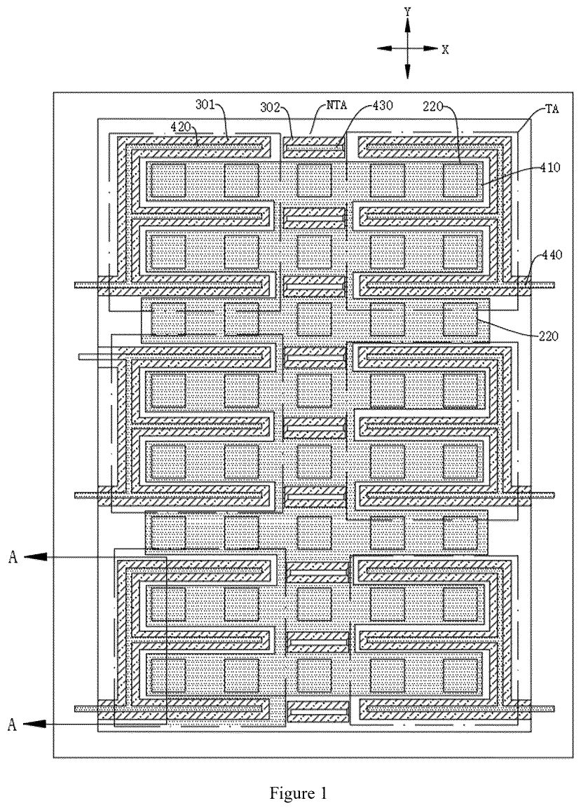

In order to better understand the present disclosure, a display panel and a display device according to the embodiments of the present disclosure will be described in detail below with reference to FIGS. 1 to 12.

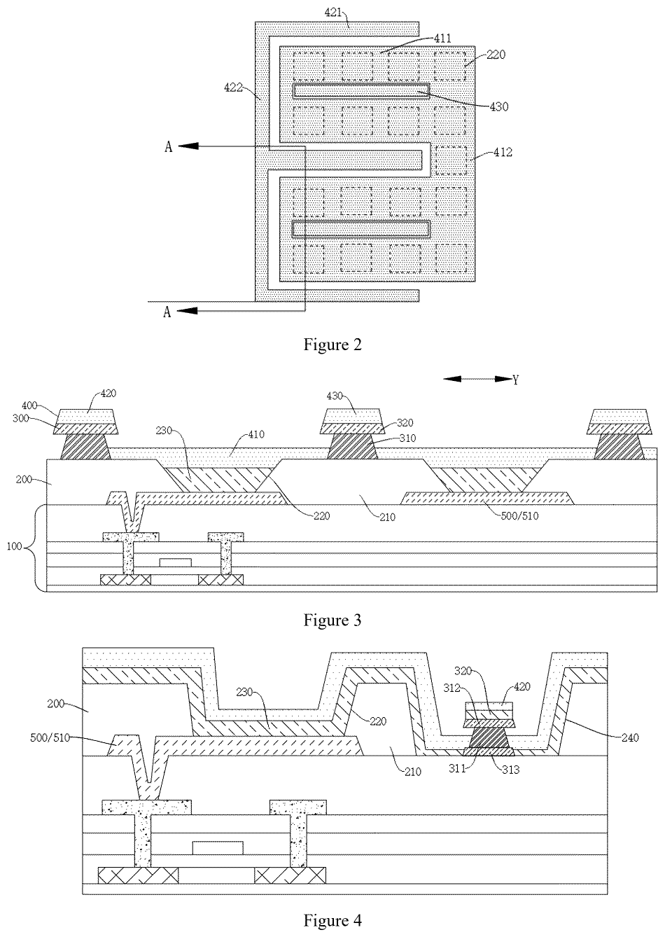

Referring to FIGS. 1 to 3 together, FIG. 1 is a top view of a display panel according to an embodiment of the present disclosure. FIG. 2 is a schematic diagram of a local enlarged structure of a display panel according to another embodiment of the present disclosure. FIG. 3 is a sectional view along line A-A in FIG. 2.

As shown in FIGS. 1 to 3, the display panel according to the embodiment of the present disclosure includes a substrate 100, a pixel defining layer 200, an isolation structure 300, and a functional layer 400. The pixel defining layer 200 is disposed on the substrate 100 and includes a pixel defining portion 210 and a pixel opening 220 within which a light-emitting unit 230 is disposed; the isolation structure 300 is disposed on the substrate 100, an orthographic projection of the isolation structure 300 on the substrate 100 is located outside an orthographic projection of the pixel opening 220 on the substrate 100, and the isolation structure 300 includes a first isolation structure 301 and a second isolation structure 302 which are spaced apart and insulated from each other; and the functional layer 400 includes a first electrode 410, a touch electrode 420 and a second electrode 430 which are insulated and spaced apart from each other, the first electrode 410 being located on a side of the light-emitting unit 230 away from the substrate 100, the touch electrode 420 being located on a side of the first isolation structure 301 away from the substrate 100, and the second electrode 430 being located on a side of the second isolation structure 302 away from the substrate 100.

In the display panel provided in the embodiment of the present disclosure, the display panel includes the substrate 100, the pixel defining layer 200, the isolation structure 300, and the functional layer 400, the pixel defining layer 200 including the pixel defining portion 210 and the pixel opening 220 within which the light-emitting unit 230 is disposed to achieve luminous display of the display panel. The orthographic projection of the isolation structure 300 on the substrate 100 is located outside the orthographic projection of the pixel opening 220 on the substrate 100 to improve the effect of the isolation structure 300 on a luminous effect of the light-emitting unit 230. The functional layer 400 includes the first electrode 410, the touch electrode 420 and the second electrode 430, the first electrode 410 being located on the side of the light-emitting unit 230 away from the substrate 100 to drive the light-emitting unit 230, and the isolation structure 300 including the first isolation structure 301 and the second isolation structure 302 which are insulated from each other, to improve a short-circuit connection between the touch electrode 420 on the first isolation structure 301 and the second electrode 430 on the second isolation structure 302. The touch electrode 420 is configured to implement a touch function of the display panel, and the functional layer 400 includes both the touch electrode 420 and the first electrode 410, simplifying the structure of the display panel without separately providing a touch structure layer. The functional layer 400 also includes the second electrode 430, and by rationally positioning the touch electrode 420 and the second electrode 430, it is possible to improve the display effect of the display panel that is affected by the addition of the touch electrode 420 in the functional layer 400.

The substrate 100 is arranged in a variety of ways, optionally, the substrate 100 may include a substrate and an array substrate, and the array substrate may include a drive circuit. For example, the array substrate may include a first signal line layer, a second signal line layer and a third signal line layer which are disposed on one side of the substrate in a stacked manner. An insulation layer is provided between adjacent signal line layers. For example, a pixel drive circuit disposed on the array substrate includes a transistor and a storage capacitor. The transistor includes a semiconductor, a gate, a source and a drain. The storage capacitor includes a first plate and a second plate. As an example, the gate and the first plate may be located in the first signal line layer, the second plate may be located in the second signal line layer, and the source and the drain may be located in the third signal line layer.

Optionally, the substrate 100 is further provided with a pixel electrode layer 500, the pixel electrode layer 500 including a plurality of pixel electrodes 510 distributed at intervals, each pixel electrode 510 being located on a side of each light-emitting unit 230 facing the substrate 100, and the pixel electrode 510 and the first electrode 410 interacting to drive the light-emitting unit 230 to emit light. One of the pixel electrode 510 and the first electrode 410 is an anode, and the other is a cathode. An embodiment of the present disclosure is exemplified by using the pixel electrode 510 as the anode.

Optionally, the isolation structure 300 may be disposed on a side of the pixel defining portion 210 away from the substrate 100. Alternatively, as shown in FIG. 4, the pixel defining portion 210 is also provided with a clearance opening 240, and the isolation structure 300 may be located in the clearance opening 240 to be in direct contact connection with the substrate 100.

Optionally, the shape of the first isolation structure 301 is adapted to the shape of the touch electrode 420, the first isolation structure 301 is present to support the touch electrode 420, and an orthographic projection of the touch electrode 420 on the substrate 100 is located within an orthographic projection of the first isolation structure 301 on the substrate 100, so that the first isolation structure 301 can separate the touch electrode 420 from the first electrode 410. Similarly, the shape of the second isolation structure 302 is adapted to the shape of the second electrode 430, the second isolation structure 302 is present to support the second electrode 430, and an orthographic projection of the second electrode 430 on the substrate 100 is located within an orthographic projection of the second isolation structure 302 on the substrate 100, so that the second isolation structure 302 can separate the second electrode 430 from the first electrode 410.

Optionally, in preparing the functional layer 400, a layer of conductive material may be deposited directly on a side of the pixel defining layer 200 and the isolation structure 300 away from the substrate 100, the conductive material falling within the pixel opening 220 forms the first electrode 410, the conductive material falling on the first isolation structure 301 forms the touch electrode 420, and the conductive material falling on the second isolation structure 302 forms the second electrode 430.

Optionally, the shapes of the first electrode 410, the touch electrode 420 and the second electrode 430 in the functional layer 400 are adapted to each other, and the first electrode 410, the touch electrode 420 and the second electrode 430 form a complete layer of conductive material. Optionally, the functional layer 400 further includes a signal line 440, where the signal line 440 is configured to connect the touch electrode 420, and the signal line 440 is configured to connect the touch electrode 420 to components such as a processor.

In some optional embodiments, as shown in FIG. 1, the display panel includes a plurality of touch areas TA, each of which is provided with the touch electrode 420, a non-touch area NTA is formed between two adjacent touch areas TA, and the non-touch area NTA is provided with the second electrode 430.

In these optional embodiments, the display panel includes a plurality of touch areas TA within which touch electrodes 420 are disposed to implement the touch function of the display panel.

Optionally, the plurality of touch areas TA are distributed in an array in a first direction X and a second direction Y, so that the display panel is provided with the touch areas TA at different positions, which can increase the area of distribution of the touch function on the display panel.

A non-touch area NTA is formed between two adjacent touch areas TA, resulting in a display disparity between the touch area TA and the non-touch area NTA due to the absence of touch electrode 420 within the non-touch area NTA. In the state where the display panel is in a standby mode, due to the different distribution area of a conductive metal material in the touch area TA and the non-touch area NTA, the display disparity between the touch area TA and the non-touch area NTA is large. In an embodiment of the present disclosure, by providing the second electrode 430 within the non-touch area NTA, the distribution density of the conductive material in the touch area TA and the non-touch area NTA tends to be uniform, thereby improving the display disparity between the touch area TA and the non-touch area NTA.

The touch electrode 420 may be shaped in a variety of ways, for example, the touch electrode 420 may be strip-shaped and located between two adjacent rows or columns of pixel openings 220. Alternatively, the touch electrode 420 may be dot-shaped or block-shaped.

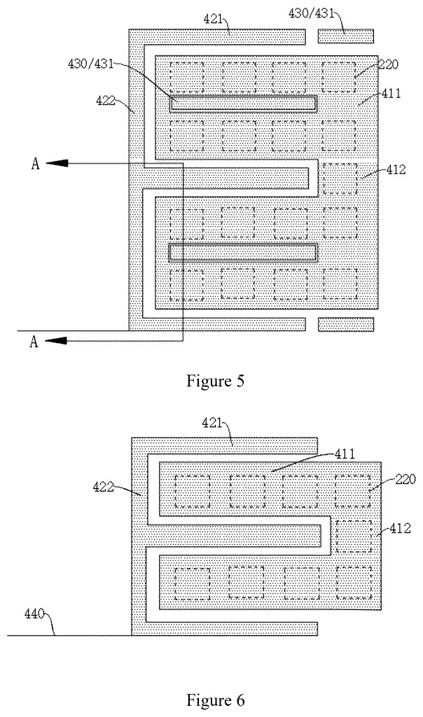

In some other optional embodiments, as shown in FIG. 5, the touch electrode 420 includes a first touch portion 421 and a second touch portion 422, the first touch portion 421 being arranged to extend in the first direction X, a plurality of first touch portions 421 being distributed at intervals in the second direction Y, and the second touch portion 422 connecting two adjacent first touch portions 421; where a plurality of pixel openings 220 are distributed in an array in the first direction X and the second direction Y, two or more rows of pixel openings 220 are arranged between two adjacent first touch portions 421, and the second electrode 430 is correspondingly arranged between the two adjacent first touch portions 421 and between two adjacent rows of pixel openings 220.

In these optional embodiments, the touch electrode 420 includes a first touch portion 421 and a second touch portion 422, the first touch portion 421 extending in the first direction X and being located between two adjacent rows of pixel openings 220, and the second touch portion 422 being configured to connect two adjacent first touch portions 421, so that the first touch portion 421 and the second touch portion 422 can be electrically connected to each other to form the electrode block described above.

The provision of two or more rows of pixel openings 220 between two adjacent first touch portions 421 results in the provision of a first touch portion 421 between two adjacent rows of pixel openings 220 on the one hand, and the provision of no first touch portion 421 between two adjacent rows of pixel openings 220 on the other hand. The uneven distribution of the conductive material may cause the display disparity. In an embodiment of the present disclosure, the display disparity caused by the above-mentioned non-uniform conductive material can be improved by providing the second electrode 430 between two adjacent first touch portions 421 and between two adjacent rows of pixel openings 220, thereby further improving the display effect of the display panel.

Optionally, the first touch portion 421 and the second touch portion 422 are connected to each other to form the touch electrode 420, and one or more electrode blocks may be provided in the same touch area TA. Optionally, the touch electrode 420 may be a self-capacitive touch electrode 420 or a mutual-capacitive touch electrode 420.

Optionally, in other embodiments, as shown in FIG. 6, a row of pixel openings 220 may also be correspondingly arranged between two adjacent first touch portions 421, and at this time, no second electrode 430 may be arranged between the two adjacent first touch portions 421.

Optionally, the shape of the first isolation structure 301 is adapted to the shape of the touch electrode 420, the first isolation structure 301 may include a first isolation portion and a second isolation portion, the first touch portion 421 is located on a side of the first isolation portion away from the substrate 100, and the second touch portion 422 is located on a side of the second isolation portion away from the substrate 100.

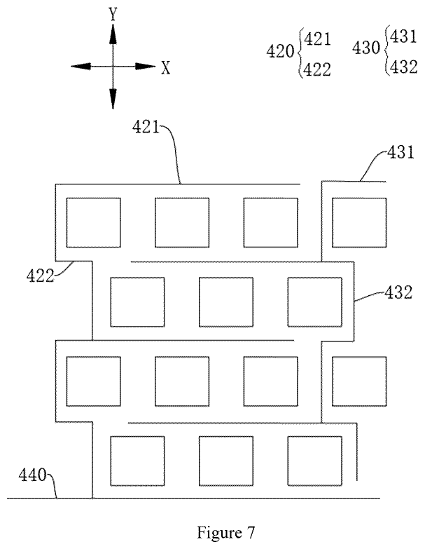

Optionally, the second touch portion 422 may be strip-shaped or serrated, etc. For example, as shown in FIGS. 1 to 6, when a plurality of pixel openings 220 are arranged in the first direction X and the second direction Y, and two adjacent rows of pixel openings 220 are aligned, the second touch portion 422 may be strip-shaped and extend between two adjacent columns of pixel openings 220. As shown in FIG. 7, when two adjacent rows of pixel openings 220 are misaligned, the second touch portion 422 may extend along a bend path to misalign with the pixel openings 220. The touch electrode 420 in one of the touch areas TA and the second electrode 430 are merely schematically shown in FIG. 7, and the first touch portion 421 and the second touch portion 422 of the touch electrode 420 are schematically shown in a line structure. The second electrode 430 is schematically shown in a line structure. The first touch portion 421 and the second touch portion 422 of the touch electrode 420, and the second electrode 430 may be a metal trace structure having a certain width as shown in FIGS. 1 and 2.

For example, as shown in FIGS. 5 and 6, when the plurality of pixel openings 220 are arranged in rows and columns along the first direction X and the second direction Y, the first direction X is a row direction, the second direction Y is a column direction, two adjacent rows of pixel openings 220 are aligned in the second direction Y, and two adjacent columns of pixel openings 220 are aligned in the first direction X. Then the first touch portion 421 may extend in the first direction X in the shape of a strip, and the second touch portion 422 may be strip-shaped in the second direction Y.

In some other optional embodiments, as shown in FIG. 7, when two adjacent rows of pixel openings 220 are misaligned, and two or more rows of pixel openings 220 are arranged between the two first touch portions 421, in order to avoid positional interference between the second touch portion 422 and the pixel opening 220, the second touch portion 422 may be bent or tilted such that the second touch portion 422 may avoid the position of the pixel opening 220.

Optionally, when the second electrode 430 is correspondingly arranged between the two adjacent first touch portions 421 and between two adjacent rows of pixel openings 220, the width of the second electrode 430 in the second direction Y is the same as the width of the first touch portion 421 in the second direction Y. The distribution of the conductive material is more balanced, and the display effect of the display panel may be better improved.

In some optional embodiments, the first electrode 410 includes a first sub-electrode portion 411 and a second sub-electrode portion 412, the first sub-electrode portion 411 being located between two adjacent first touch portions 421, a plurality of first sub-electrode portions 411 being arranged at intervals in the second direction Y, and the second sub-electrode portion 412 connecting two adjacent first sub-electrode portions 411.

In these optional embodiments, the first sub-electrode portion 411 is located between two adjacent first touch portions 421, and the first sub-electrode portion 411 is configured to drive light emission from the light-emitting unit 230 located within the pixel opening 220 between the two adjacent first touch portions 421. The second sub-electrode portion 412 is configured to connect the plurality of first sub-electrode portions 411 into a continuous electrode.

Optionally, as shown in FIGS. 1 and 2, the display panel includes a display area AA, and the second sub-electrode portion 412 is configured to connect the plurality of first sub-electrode portions 411 into a continuous electrode, the continuous electrode does not necessarily have to be an electrode that is physically laid out over the entire surface, meaning it does not have to be laid out over the entire display area AA, but may interconnect the first sub-electrode portions 411 and the second sub-electrode portion 412 in the display area AA, and the first sub-electrode portions 411 and the second sub-electrode portion 412 in the display area AA have the same potential. Optionally, the display panel may also include a non-display area AA arranged around the display area AA.

In an embodiment of the present disclosure, when the touch electrode 420 is comb-shaped and includes a first touch electrode 420 portion and a second touch electrode 420 portion, the first electrode 410 is also comb-shaped and includes the first sub-electrode portion 411 and the second sub-electrode portion 412, and the touch electrode 420 and the first electrode 410 are substantially interconnected, which can increase the distribution area of the touch electrode 420 and the first electrode 410, and improves the sensitivity of the touch function without affecting a luminous effect of the display panel. In addition, by adding the second electrode 430 in the non-touch area NTA or the touch area TA, it is possible to improve the display effect of the display panel that is affected by the uneven distribution of the conductive material caused by the provision of the touch electrode 420.

Optionally, at least a part of the second sub-electrode portion 412 and the second touch portion 422 are respectively arranged on two sides of the same first touch portion 421 in the first direction X. For example, the second touch portion 422 connected to a certain first touch portion 421, and the second sub-electrode portion 412 for connecting the first sub-electrode portions 411 located on two sides of the first touch portion 421 are respectively arranged on two sides of the first touch portion 421 in the first direction X, so that the arrangement of the second sub-electrode portion 412 and the second touch portion 422 does not affect each other. The shape of the touch electrode 420 and the shape of the first electrode 410 are adapted to each other to increase the distribution area of the touch electrode 420 and the first electrode 410.

Optionally, the second electrode 430 is arranged between the first touch portion 421 and the first sub-electrode portion 411 which are adjacent to each other. For example, when two or more rows of pixel openings 220 are arranged between two adjacent first touch portions 421, two or more first sub-electrode portions 411 may be arranged between the two adjacent first touch portions 421, each first sub-electrode portion 411 corresponding to each row of pixel openings 220, and the first sub-electrode portion 411 being configured to drive the light-emitting units 230 in the same row of pixel openings 220 to emit light. At this time, the second electrode 430 may be arranged between two adjacent first sub-electrode portions 411 to increase the distribution area of the second electrode 430 and to make the distribution of the touch electrode 420 and the second electrode 430 more balanced, thereby improving the display effect of the display panel.

In some optional embodiments, the second electrode 430 includes a first virtual electrode 431, the first virtual electrode 431 being located between two adjacent first touch portions 421 in the first direction X, and the first virtual electrode 431 being arranged to extend in the first direction X.

In these optional embodiments, the second electrode 430 includes a first virtual electrode 431, and the first virtual electrode 431 extends in the first direction X such that the shapes of the first virtual electrode 431 and the first touch portion 421 are more similar, which can improve the display disparity due to a gap between two adjacent first touch portions 421 in the first direction X.

Optionally, as shown in FIG. 1, the first virtual electrode 431 is located between the adjacent first touch portions 421 in the first direction X. For example, the first virtual electrode 431 is located between the first touch portions 421 of the adjacent touch areas TA in the first direction X, so as to improve the display disparity between the touch area TA and the non-touch area NTA of the display panel.

Optionally, the first virtual electrode 431 extends by the same width as the first touch portion 421 in the second direction Y. The shape of the first virtual electrode 431 and the shape of the first touch portion 421 are more similar, which better improves the display disparity due to the gap between the two adjacent first touch portions 421 in the first direction X.

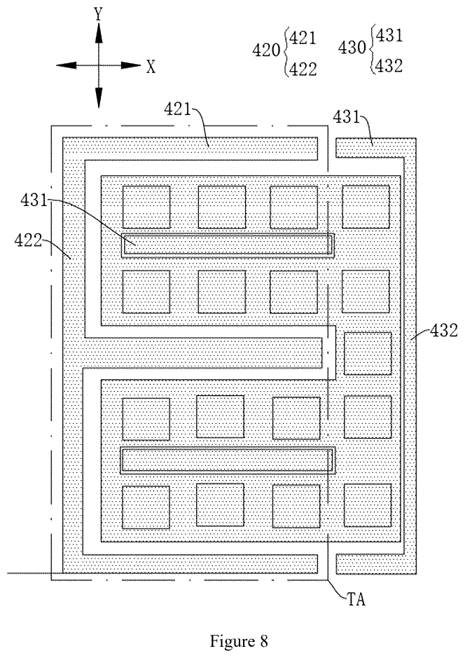

In some optional embodiments, as shown in FIGS. 7 and 8, a plurality of first virtual electrodes 431 are arranged side by side in the second direction Y, the second electrode 430 includes a second virtual electrode 432, and the second virtual electrode 432 connects two adjacent first virtual electrodes 431 in the second direction Y.

In these optional embodiments, by adding the second virtual electrode 432, the second electrode 430 includes the first virtual electrode 431 and the second virtual electrode 432, and the second electrode 430 has a more similar shape than the touch electrode 420 including the first touch portion 421 and the second touch portion 422, to better improve the display effect of the display panel.

Optionally, the shape of the second isolation structure 302 is adapted to the shape of the second electrode 430. When the second electrode 430 includes the first virtual electrode 431 and the second virtual electrode 432, the second isolation structure 302 may include a third isolation portion and a fourth isolation portion, the first virtual electrode 431 being located on a side of the third isolation portion away from the substrate 100, and the second virtual electrode 432 being located on a side of the fourth isolation portion away from the substrate 100. Optionally, an orthographic projection of the first virtual electrode 431 on the substrate 100 is located within an orthographic projection of the third isolation portion on the substrate 100, and an orthographic projection of the second virtual electrode 432 on the substrate 100 is located within an orthographic projection of the fourth isolation portion on the substrate 100.

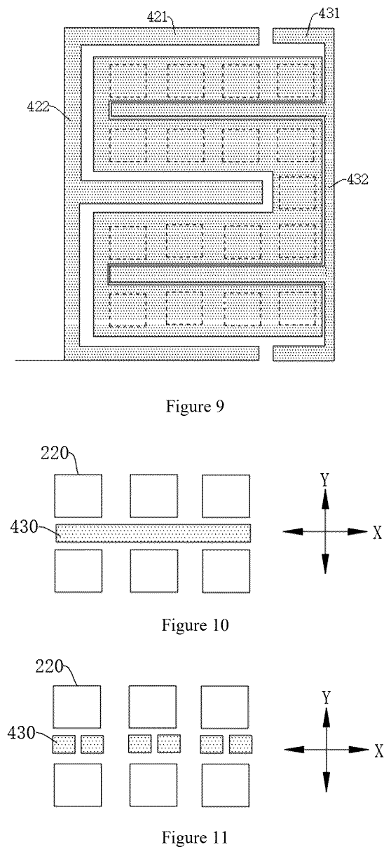

Optionally, the first virtual electrode 431 may be provided in the touch area TA, and the second virtual electrode 432 may be connected to the first virtual electrode 431 in the non-touch area NTA. Alternatively, as shown in FIG. 9, the second virtual electrode 432 may be connected to the first virtual electrodes 431 in the touch area TA and the non-touch area NTA. The length of the first virtual electrode 431 in the touch area TA may be the same as or different from the length of the first virtual electrode 431 in the non-touch area NTA in the first direction X.

Optionally, the shape of an extension path of the second virtual electrode 432 is the same as the shape of an extension path of the second touch portion 422. For example, as shown in FIG. 7, when the second touch portion 422 extends along the bend path, the second virtual electrode 432 extends along the bend path. Alternatively, as shown in FIGS. 8 and 9, when the second touch portion 422 extends in the second direction Y in the shape of a strip, the second virtual electrode 432 extends in the second direction Y in the shape of a strip, so that the shape of the second electrode 430 is more adapted to the shape of the touch electrode 420, thereby better improving the display effect of the display panel.

Optionally, the second virtual electrode 432 extends by the same width in the first direction X as the second touch portion 422 in the first direction X, so that the shape of the second electrode 430 is more adapted to the shape of the touch electrode 420, thereby better improving the display effect of the display panel.

In some optional embodiments, as shown in FIG. 1, the display panel includes a plurality of touch areas TA, the plurality of touch areas TA being distributed in an array in the first direction X and the second direction Y, and two adjacent touch areas TA are equidistant in the first direction X and/or the second direction Y. The distribution of the plurality of touch areas TA is made more even, so that the display effect of the display panel is more even.

Optionally, the width of the second electrode 430 between two adjacent touch areas TA in the first direction X is the same, and/or the length of the second electrode 430 between two adjacent touch areas TA in the second direction Y is the same. The distribution of a plurality of second electrodes 430 is made more even, so that the display effect of the display panel is more even.

Optionally, the number of touch electrodes 420 provided in each touch area TA is the same, so that the touch electrodes 420 are more evenly distributed in the plurality of touch areas TA, achieving a more even display effect of the display panel.

In some optional embodiments, as shown in FIG. 10, the plurality of pixel openings 220 are distributed in an array in the first direction X and the second direction Y, the first direction X is the row direction, and the second electrode 430 is correspondingly located between two adjacent rows of pixel openings 220, so as to improve the effect of the second electrode 430 on the display effect.

Optionally, as shown in FIG. 11, the plurality of second electrodes 430 are arranged side by side at intervals in the first direction X, i.e., the same pixel opening 220 may correspond to the plurality of second electrodes 430, to make the shaping of the second electrodes 430 more extensive.

Optionally, as shown in FIG. 10, the second electrode 430 and one or more pixel openings 220 are arranged side by side in the second direction Y. When the second electrode 430 and the plurality of pixel openings 220 are arranged side by side in the second direction Y, the shape of the second electrode 430 is more adapted to the shape of the touch electrode 420 to better improve the display effect of the display panel. When the second electrode 430 and the single pixel opening 220 are arranged side by side in the second direction Y, it is possible to reduce the distribution area of the second electrode 430, increase the distribution area of the first electrode 410, and decrease the resistance of the first electrode 410.

Alternatively, the plurality of second electrodes 430 and the same pixel opening 220 are arranged side by side in the second direction Y, to diversify the shaping of the second electrodes 430, so that the second electrodes 430 are arranged in various shapes in different positions to improve the display effect of the display panel.

In some optional embodiments, as shown in FIG. 3, the first isolation structure 301 includes a conductive portion 310 and an insulating portion 320 located on a side of the conductive portion 310 away from the substrate 100, and the touch electrode 420 is located on a side of the insulating portion 320 away from the substrate 100; and/or, the second isolation structure 302 includes a conductive portion 310 and an insulating portion 320 located on a side of the conductive portion 310 away from the substrate 100, and the touch electrode 420 is located on a side of the insulating portion 320 away from the substrate 100, where the first electrode 410 and the conductive portion 310 are electrically connected to each other.

In these optional embodiments, the first electrode 410 and the conductive portion 310 are electrically connected to each other, such that the first electrodes 410 can be interconnected by the conductive portion 310 into a continuous electrode, and the impedance of the first electrode 410 can be reduced.

The insulating portion 320 is provided in a variety of materials, for example, the insulating portion 320 may include an organic insulation layer and/or an inorganic insulation layer, i.e., the material of the insulating portion 320 may include an organic insulating material and/or an inorganic insulating material.

Optionally, an orthographic projection of the conductive portion 310 on the substrate 100 is located within an orthographic projection of the insulating portion 320 on the substrate 100, i.e., the size of the conductive portion 310 is less than or equal to the size of the insulating portion 320, so that a segment difference can be formed between the conductive portion 310 and the insulating portion 320, or one side of the conductive portion 310 can form a recess, and the functional layer 400 can break at the edge of the isolation structure 300 to form the first electrode 410 and the touch electrode 420.

Optionally, as shown in FIGS. 1 to 4, the conductive portion 310 includes a first sub-layer 311 and a second sub-layer 312 located on a side of the first sub-layer 311 away from the substrate 100, the first sub-layer 311 and the first electrode 410 being electrically connected to each other, an orthographic projection of the first sub-layer 311 on the substrate 100 being located within an orthographic projection of the second sub-layer 312 on the substrate 100, and the orthographic projection of the second sub-layer 312 on the substrate 100 being located within an orthographic projection of the insulating portion 320 on the substrate 100. That is, the cross-sectional dimension of the first sub-layer 311 is less than or equal to that of the second sub-layer 312, making it easier for the functional layer 400 to break at the edge of the isolation structure 300 to form the first electrode 410 and the touch electrode 420.

Optionally, as shown in FIG. 4, the conductive portion 310 further includes a third sub-layer 313 on a side of the first sub-layer 311 facing the substrate 100, the orthographic projection of the first sub-layer 311 on the substrate 100 being located within an orthographic projection of the third sub-layer 313 on the substrate 100, that is, the cross-sectional dimension of the first sub-layer 311 is less than or equal to that of the third sub-layer 313, enabling the first electrode 410 to more easily climb over the third sub-layer 313 to the first sub-layer 311 and to be electrically connected to the first sub-layer 311.

Optionally, the material of the second sub-layer 312 is the same as the material of the third sub-layer 313 so as to simplify a preparation process for the display panel.

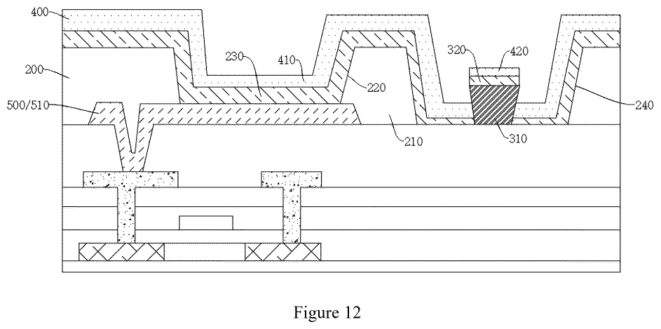

Optionally, as shown in FIG. 12, the conductive portion 310 is a single-layer structural body, the cross-sectional area of the conductive portion 310 is gradually reduced in a direction from the conductive portion 310 to the substrate 100, so that one side of the conductive portion 310 can form a recess, and the first electrode 410 and the touch electrode 420 can break at the edge of the conductive portion 310.

As mentioned above, the material of the insulating portion 320 includes an organic material and/or an inorganic material. Optionally, as shown in FIG. 12, the light-emitting unit 230 includes a carrier layer, and the material of the insulating portion 320 may be the same as the material of the carrier layer, so that the insulating portion 320 and the carrier layer may be formed in the same process step. The carrier layer may include at least one of a hole injection layer, a hole transport layer, an electron blocking layer, a hole blocking layer, an electron transport layer and an electron injection layer.

Alternatively, the material of the insulating portion 320 includes an inorganic material such that the thickness of the insulating portion 320 is thin, or the material of the insulating portion 320 includes an organic material such that the thickness of the insulating portion 320 is thick. Alternatively, the material of the insulating portion 320 includes an organic material and an inorganic material, i.e., the insulating portion 320 includes two sub-layers to further increase the thickness of the insulating portion 320, enabling the first electrode 410 and the touch electrode 420 to break at the edge of the isolation structure 300.

As shown in FIGS. 1 to 11, yet another embodiment in the first aspect of the present disclosure further provides a display panel, including: a substrate 100; a pixel defining layer 200 disposed on the substrate 100 and including a pixel defining portion 210 and a pixel opening 220; a light-emitting layer including a light-emitting unit 230 located in the pixel opening 220; and a functional layer 400 disposed on a side of the light-emitting layer and the pixel defining layer 200 away from the substrate 100, the functional layer 400 including a first electrode 410, a touch electrode 420 and a second electrode 430 which are insulated and spaced apart from each other, the first electrode 410 being located on a side of the light-emitting unit 230 away from the substrate 100.

The display panel according to the embodiment of the present disclosure includes a substrate 100, a pixel defining layer 200, a light-emitting layer, and a functional layer 400. The pixel defining layer 200 includes a pixel defining portion 210 and a pixel opening 220, and a light-emitting unit 230 of the light-emitting layer is located within the pixel opening 220 to achieve luminous display of the display panel. The functional layer 400 includes a first electrode 410, a touch electrode 420 and a second electrode 430, the first electrode 410 being located on a side of the light-emitting unit 230 away from the substrate 100 to drive the light-emitting unit 230 to emit light. The touch electrode 420 is configured to implement the touch function and simplify the structure of the display panel, and the second electrode 430 is configured to equalize the distribution pattern and the distribution area of the functional layer 400, so as to improve the display effect of the display panel.

In some optional embodiments, the display panel further includes an isolation structure 300, the isolation structure 300 being disposed on one side of the substrate 100, an orthographic projection of the isolation structure 300 on the substrate 100 being located outside an orthographic projection of the pixel opening 220 on the substrate 100, the isolation structure 300 including a first isolation structure 301 and a second isolation structure 302 which are spaced apart and insulated from each other, the touch electrode 420 being located on a side of the first isolation structure 301 away from the substrate 100, and the second electrode 430 being located on a side of the second isolation structure 302 away from the substrate 100. By adding the first isolation structure 301 and the second isolation structure 302, the first electrode 410, the touch electrode 420 and the second electrode 430 can be insulated and separated from each other.

Optionally, the first electrode 410 and the isolation structure 300 are electrically connected to allow for a complete interconnection of the plurality of first electrodes 410 in the display panel.

In the embodiment of the present disclosure, the substrate 100, the pixel defining layer 200, the isolation structure 300 and the functional layer 400 are arranged in such a manner as described above, which will not be repeated herein.

As shown in FIGS. 1 to 11, an embodiment in the first aspect of the present disclosure further provides a display panel, including: a substrate 100; an isolation structure 300 disposed on the substrate 100, the isolation structure 300 enclosing an isolation opening, and the isolation structure 300 including a first isolation structure 301 and a second isolation structure 302 which are spaced apart and insulated from each other; a light-emitting layer including a light-emitting unit 230 located at the isolation opening; and a functional layer 400 including a first electrode 410, a touch electrode 420 and a second electrode 430 which are insulated and spaced apart from each other, the first electrode 410 being located on a side of the light-emitting unit 230 away from the substrate 100, the touch electrode 420 being located on a side of the first isolation structure 301 away from the substrate 100, and the second electrode 430 being located on a side of the second isolation structure 302 away from the substrate 100.

The display panel according to the embodiment of the present disclosure includes a substrate 100, a pixel defining layer 200, a light-emitting layer, and a functional layer 400. The isolation structure 300 includes an isolation opening within which a light-emitting unit 230 of the light-emitting layer is disposed to achieve luminous display of the display panel. The functional layer 400 includes a first electrode 410, a touch electrode 420 and a second electrode 430, the first electrode 410 being located on a side of the light-emitting unit 230 away from the substrate 100 to drive the light-emitting unit 230 to emit light. The touch electrode 420 is configured to implement the touch function and simplify the structure of the display panel, and the second electrode 430 is configured to equalize the distribution pattern and the distribution area of the functional layer 400, so as to improve the display effect of the display panel.

In some optional embodiments, the first isolation structure 301 and the second isolation structure 302 each include a conductive portion 310 and an insulating portion 320 located on a side of the conductive portion 310 away from the substrate 100, the touch electrode 420 and the second electrode 430 are located on a side of the insulating portion 320 away from the substrate 100, and the first electrode 410 and the conductive portion 310 are connected to each other.

In these optional embodiments, the first isolation structure 301 and the second isolation structure 302 each include a conductive portion 310 and an insulating portion 320, the conductive portion 310 and the first electrode 410 being connected such that the first electrodes 410 are interconnected into a continuous electrode. The insulating portion 320 on the conductive portion 310 can mitigate the problem of a short-circuit connection between the first electrode 410 and the touch electrode 420 and between the first electrode 410 and the second electrode 430.

Optionally, the first isolation structure 301 and the second isolation structure 302 are spaced apart to create a gap, an orthographic projection of the light-emitting unit 230 on the substrate 100 is outside the gap, and at least a part of the first electrode 410 is located in the gap to connect the conductive portions 310 of the first isolation structure 301 and the second isolation structure 302.

In these embodiments, the first isolation structure 301 and the second isolation structure 302 are spaced apart from each other to mitigate the problem of a short-circuit connection between the touch electrode 420 on the first isolation structure 301 and the second electrode 430 on the second isolation structure 302, and the first electrode 410 is provided in the gap between the first isolation structure 301 and the second isolation structure 302 to connect the conductive portions 310 of the first isolation structure 301 and the second isolation structure 302, so that the first electrodes 410 may be interconnected into a continuous electrode to reduce the resistance of the first electrode 410.

In the embodiment of the present disclosure, the substrate 100, the pixel defining layer 200, the isolation structure 300 and the functional layer 400 are arranged in such a manner as described above, which will not be repeated herein.

An embodiment in a second aspect of the present disclosure further provides a display device, including a display panel according to any one of the above-described embodiments in the first aspect. Since the display device according to the embodiment in the second aspect of the present disclosure includes the display panel according to any one of the above-described embodiments in the first aspect, the display device according to the embodiment in the second aspect of the present disclosure has the beneficial effects of the display panel according to any one of the above-described embodiments in the first aspect, which will not be repeated herein.

The display device in the embodiment of the present disclosure includes, but is not limited to devices having a display function, such as a cell phone, a personal digital assistant (PDA), a tablet computer, an e-book, a television, an access control, a smart fixed-line telephone, or a control console.

Although the present disclosure is described with reference to the preferred embodiments, various modifications can be made, and equivalents can be provided to substitute for the components thereof without departing from the scope of the present disclosure. In particular, the technical features mentioned in the embodiments can be combined in any manner, provided that there is no structural conflict. The present disclosure is not limited to the specific embodiments disclosed herein but includes all the technical solutions that fall within the scope of the claims.

What is claimed is:

1. A display panel, comprising:
a substrate;
a pixel defining layer disposed on the substrate and comprising a pixel defining portion and a pixel opening within which a light-emitting unit is disposed;
an isolation structure disposed on the substrate, an orthographic projection of the isolation structure on the substrate being located outside an orthographic projection of the pixel opening on the substrate, and the isolation structure including a first isolation structure and a second isolation structure which are spaced apart and insulated from each other; and
a functional layer comprising a first electrode, a touch electrode and a second electrode which are insulated and spaced apart from each other, the first electrode being located on a side of the light-emitting unit away from the substrate, the touch electrode being located on a side of the first isolation structure away from the substrate, and the second electrode being located on a side of the second isolation structure away from the substrate.

2. The display panel according to claim 1, wherein the display panel comprises a plurality of touch areas, each of the touch areas is provided with the touch electrode, a non-touch area is formed between two adjacent ones of the touch areas, and the non-touch area is provided with the second electrode; and
the plurality of touch areas are distributed in an array in a first direction and a second direction.

3. The display panel according to claim 2, wherein the touch electrode comprises:
a first touch portion arranged to extend in the first direction, a plurality of first touch portions being distributed at intervals in the second direction; and
a second touch portion connecting two adjacent ones of the first touch portions;
wherein a plurality of pixel openings are distributed in an array in the first direction and the second direction, at least two rows of pixel openings are arranged between two adjacent ones of the first touch portions, and the second electrode is correspondingly arranged between the two adjacent ones of the first touch portions and between two adjacent rows of pixel openings; and
the width of the second electrode in the second direction is the same as the width of the first touch portion in the second direction.

4. The display panel according to claim 3, wherein the first electrode comprises a first sub-electrode portion and a second sub-electrode portion, the first sub-electrode portion being located between two adjacent ones of the first touch portions, a plurality of first sub-electrode portions being arranged at intervals in the second direction, and the second sub-electrode portion connecting two adjacent ones of the first sub-electrode portions; and
the second electrode is arranged between two adjacent ones of the first touch portions and between two adjacent ones of the first sub-electrode portions.

5. The display panel according to claim 4, wherein at least a part of the second sub-electrode portion and the second touch portion are respectively arranged on two sides of the same first touch portion in the first direction.

6. The display panel according to claim 3, wherein the second electrode comprises a first virtual electrode arranged to extend in the first direction; and
the first virtual electrode is located between two adjacent ones of the first touch portions in the first direction; and
the first virtual electrode extends by the same width as the first touch portion in the second direction.

7. The display panel according to claim 6, wherein a plurality of first virtual electrodes are arranged side by side in the second direction, and the second electrode further comprises a second virtual electrode connecting two adjacent ones of the first virtual electrodes in the second direction; and
the shape of an extension path of the second virtual electrode is the same as the shape of an extension path of the second touch portion; and
the second virtual electrode extends by the same width in the first direction as the second touch portion in the first direction.

8. The display panel according to claim 2, wherein
two adjacent ones of the touch areas are spaced apart by the same distance at least one of in the first direction and the second direction;
the width of the second electrode between two adjacent ones of the touch areas in the first direction is the same, and the length of the second electrode between two adjacent ones of the touch areas in the second direction is the same; or
the width of the second electrode between two adjacent ones of the touch areas in the first direction is the same, or the length of the second electrode between two adjacent ones of the touch areas in the second direction is the same; and
the number of touch electrodes provided in each of the touch areas is the same.

9. The display panel according to claim 1, wherein a plurality of pixel openings are distributed in an array in a first direction and a second direction, the first direction being a row direction, and the second electrode being correspondingly located between two adjacent rows of pixel openings; and
a plurality of second electrodes are arranged side by side at intervals in the first direction; and
the second electrode and one or more of the pixel openings are arranged side by side in the second direction, or the plurality of second electrodes and the same pixel opening are arranged side by side in the second direction.

10. The display panel according to claim 1, wherein
the isolation structure is disposed on a side of the pixel defining portion away from the substrate;
or the pixel defining portion also encloses a clearance opening, and the isolation structure is located in the clearance opening and is spaced apart from an inner wall surface of the pixel defining portion facing the clearance opening.

11. The display panel according to claim 1, wherein
the first isolation structure comprises a conductive portion and an insulating portion on a side of the conductive portion away from the substrate, the touch electrode being located on a side of the insulating portion away from the substrate,
and the second isolation structure comprises a conductive portion and an insulating portion on a side of the conductive portion away from the substrate, the second electrode being located on a side of the insulating portion away from the substrate,
wherein the first electrode and the conductive portion are electrically connected to each other; and
the insulating portion comprises at least one of an inorganic insulation layer and an organic insulation layer.

12. The display panel according to claim 11, wherein an orthographic projection of the conductive portion on the substrate is located within an orthographic projection of the insulating portion on the substrate.

13. The display panel according to claim 11, wherein the conductive portion comprises a first sub-layer and a second sub-layer on a side of the first sub-layer away from the substrate, the first sub-layer and the first electrode being electrically connected to each other, an orthographic projection of the first sub-layer on the substrate being located within an orthographic projection of the second sub-layer on the substrate, and the orthographic projection of the second sub-layer on the substrate being located within an orthographic projection of the insulating portion on the substrate.

14. The display panel according to claim 13, wherein the conductive portion further comprises a third sub-layer on a side of the first sub-layer facing the substrate, the orthographic projection of the first sub-layer on the substrate being located within an orthographic projection of the third sub-layer on the substrate; and
the second sub-layer and the third sub-layer are made of the same material.

15. A display panel, comprising:
a substrate;
a pixel defining layer disposed on the substrate and comprising a pixel defining portion and a pixel opening;
a light-emitting layer comprising a light-emitting unit located in the pixel opening; and
a functional layer disposed on a side of the light-emitting layer and the pixel defining layer away from the substrate, the functional layer comprising a first electrode, a touch electrode and a second electrode which are insulated and spaced apart from each other, the first electrode being located on a side of the light-emitting unit away from the substrate.

16. The display panel according to claim 15, wherein the display panel further comprises an isolation structure disposed on one side of the substrate, an orthographic projection of the isolation structure on the substrate being located outside an orthographic projection of the pixel opening on the substrate, the isolation structure comprising a first isolation structure and a second isolation structure which are spaced apart and insulated from each other, the touch electrode being located on a side of the first isolation structure away from the substrate, and the second electrode being located on a side of the second isolation structure away from the substrate; and
the first electrode is electrically connected to the isolation structure.

17. A display panel, comprising:
a substrate;
an isolation structure disposed on the substrate, the isolation structure enclosing an isolation opening, and the isolation structure comprising a first isolation structure and a second isolation structure which are spaced apart and insulated from each other;
a light-emitting layer comprising a light-emitting unit located in the isolation opening; and
a functional layer comprising a first electrode, a touch electrode and a second electrode which are insulated and spaced apart from each other, the first electrode being located on a side of the light-emitting unit away from the substrate, the touch electrode being located on a side of the first isolation structure away from the substrate, and the second electrode being located on a side of the second isolation structure away from the substrate.

18. The display panel according to claim 17, wherein the first isolation structure and the second isolation structure each comprises a conductive portion and an insulating portion on a side of the conductive portion away from the substrate, the touch electrode and the second electrode being located on a side of the insulating portion away from the substrate, and the first electrode and the conductive portion being connected to each other.

19. The display panel according to claim 18, wherein the first isolation structure and the second isolation structure are spaced apart to create a gap, an orthographic projection of the light-emitting unit on the substrate is outside the gap, and at least a part of the first electrode is located in the gap to connect the conductive portions of the first isolation structure and the second isolation structure.

20. A display device, comprising a display panel according to claim 1.
